(19) United States
(12) Patent Application Publication
(10) Pub. No.: US 2026/0363047 A1
(43) Pub. Date: Nov. 12, 2026

(54) INTEGRATED CIRCUIT DEVICE AND METHOD OF MANUFACTURE

(71) Applicant: Taiwan Semiconductor Manufacturing Company, Ltd., Hsinchu (TW)

(72) Inventors: Hung-Ling Shih, Tainan City (TW); Che-Wei Chen, Taichung City (TW); Hung-Chang Chang, Tainan City (TW)

(21) Appl. No.: 19/291,665

(22) Filed: Aug. 6, 2025

Related U.S. Application Data
(60) Provisional application No. 63/804,077, filed on May 12, 2025.

(51) Int. Cl. H10W 20/20; H10W 20/00; H10W 20/42; H10W 20/43; H10W 20/44

(52) U.S. Cl. CPC H10W 20/20; H10W 20/023; H10W 20/42; H10W 20/43; H10W 20/4421

(57) ABSTRACT

A process of forming a TSV includes forming a contact pad over a dielectric structure on a first side of a semiconductor substrate. After thinning from the second side, a hole is etched through the semiconductor substrate. The hole stops on one of the layers in the front side dielectric structure. The hole is lined with an oxide liner, then with conformal and nonconformal silicon nitride layers. An anisotropic etch process is used to etch through layers at the bottom of the hole until only oxide remains between the hole and the contact pad. The pad is exposed with a selective wet etch. Then the hole is filled with conductive material to provide the TSV. The nonconformal silicon nitride protects the TSV liner during anisotropic dry etching. The conformal silicon nitride protects the TSV liner during selective wet etching. The process avoids damage to even a thin, slotted contact pad.

### REFERENCE TO RELATED APPLICATION

This Application claims priority to U.S. Provisional Application number 63/804,077, filed on May 12, 2025, the contents of which are hereby incorporated by reference in their entirety.

### BACKGROUND

As the demand for high-performance and miniaturized semiconductor devices continues to increase, three-dimensional (3D) integration technologies have gained prominence due to their ability to enhance device density, reduce form factor, and improve electrical performance. Through Substrate Vias (TSVs) have emerged as a critical enabling technology for vertical interconnection in 3D integrated circuits (3D ICs) and wafer-level packaging. A TSV comprises a conductive plug extending through a semiconductor substrate and providing electrical connectivity between different layers or dies.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1 illustrates a cross-sectional view of an integrated circuit (IC) according to some aspects of the present disclosure.

FIG. 1A illustrates a plan view of a contact pad in the IC device of FIG. 1.

FIGS. 2 and 3 illustrates cross-sectional views of IC devices in accordance with other embodiments.

FIGS. 4-22 provide a series of cross-sectional views illustrating a process according to some aspects of the present disclosure.

FIGS. 23-26 provide a series of cross-sectional views illustrating a variation on the process of FIGS. 4-22.

FIG. 27 provides a flow chart illustrating form a process in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

In a typical process, a through-substrate via (TSV) is formed from the back side of a semiconductor substrate after front-end-of-line (FEOL), middle-of-line (MOL), and back-end-of-line (BEOL) processing. The semiconductor substrate is thinned from the back side, and a hole for the TSV is etched through the remaining substrate thickness. Due to aspect ratio limitations, the hole is typically much wider than the critical dimensions of FEOL and BEOL structures on the front side.

After etching, the hole is lined with a dielectric structure, which typically includes both an oxide layer and a silicon nitride layer. The oxide layer provides electrical insulation and adheres well to the semiconductor substrate, which may be silicon. The silicon nitride layer is deposited nonconformally, covers only an upper part of the oxide layer, and produces an overhang near the top of the hole. The overhang protect the oxide on the sidewalls during an anisotropic dry etching that removes dielectrics from the bottom of the hole to expose a contact pad previously formed during BEOL processing. A subsequent cleaning step removes etch residues from the contact pad. The hole is then filled with conductive material.

As device dimensions scale down, it becomes impractical to provide a contact pad that fully covers the bottom of the TSV hole. Instead, the contact pad may be slotted or otherwise perforated to reduce dishing during planarization. Device scaling also reduces the thickness of the contact pad along with the thickness of the layer in which the contact pad resides.

It has been determined that the conventional process can lead to contact pad failure, particularly when the pad is both thin and slotted. Specifically, the dry etch step used to expose the contact pad can partially oxidize the copper pad, making it susceptible to removal by the wet clean used to eliminate etch residues. This can result in substantial material loss and render the contact pad ineffective.

One aspect of the present disclosure is a TSV formation process that addresses this issue. The process includes anisotropic dry etching that leaves an oxide dielectric layer above the contact pad, followed by selective wet etching that etches through the oxide dielectric layer without attacking silicon nitride. To prevent the wet etching from damaging the dielectric liner, a conformal silicon nitride layer is deposited to fully cover the sidewalls of the TSV hole. This conformal layer is in addition to the nonconformal silicon nitride layer that provide the overhang for sidewall protection during anisotropic dry etching.

Accordingly, another aspect of the invention is a TSV dielectric liner that includes a conformal oxide layer, a conformal silicon nitride layer, and a nonconformal silicon nitride layer. In some embodiments, the conformal and nonconformal nitride layers are deposited in two phases of a plasma-enhanced chemical vapor deposition (PECVD) process. One phase uses reduced substrate bias to achieve conformal deposition and completely cover the sidewalls with silicon nitride, while the other uses increased substrate bias to achieve nonconformal deposition and form a silicon nitride overhang. As a result, the liner structure includes a silicon nitride overhang near the top of the TSV and a lower section with uniform silicon nitride thickness.

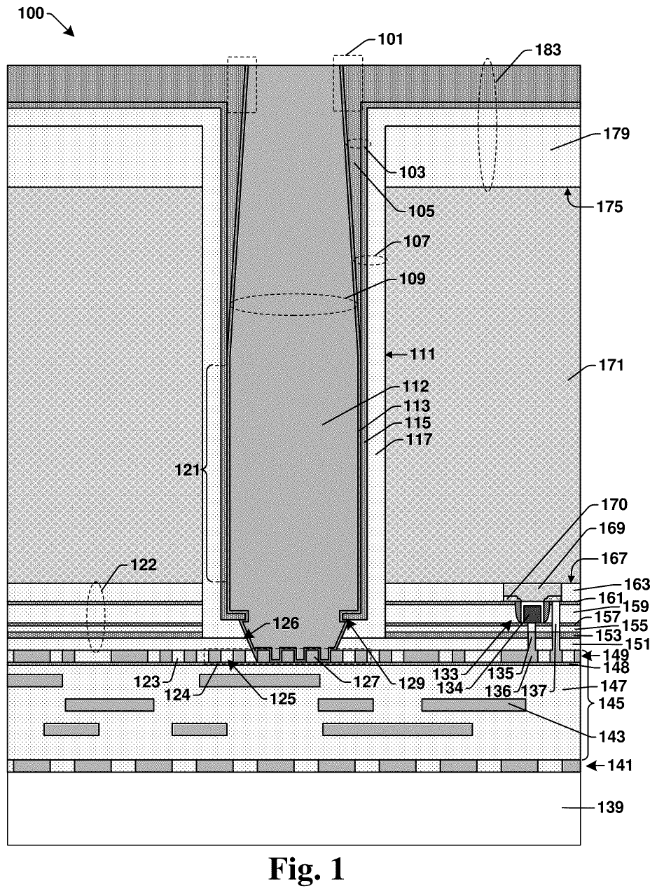

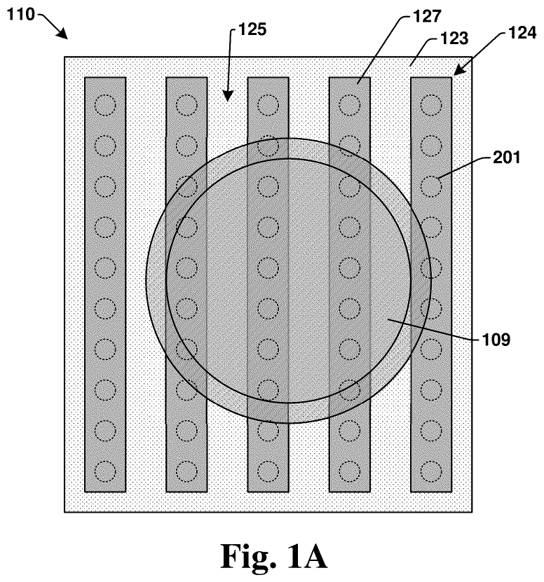

FIG. 1 illustrates a cross-sectional view of an integrated circuit (IC) device 100 having a TSV 109 extending through a semiconductor substrate 171. The TSV 109 can be a back side TSV disposed within an opening through the semiconductor substrate 171 defined by the sidewalls 111. The opening may become progressively narrower from the back side 175 of the semiconductor substrate 171 to the front side 167. The variation in width may be comparatively small and is not shown in the illustration.

In some embodiments, the mean width of the opening is in the range from about 200 nm to about 1000 nm. In some embodiments, the mean width is about 600 nm or less. In some embodiments, the aspect ratio is in the range from about 2:1 to about 5:1. These dimensions are typical for a TSV formed in an advanced semiconductor process node.

A TSV liner 107 separates the TSV 109 from the sidewalls 111 of the semiconductor substrate 171. The TSV liner 107 is a dielectric liner and includes an oxide layer 117, a conformal silicon nitride layer 115, and a nonconformal silicon nitride layer 105. Of these layers, the oxide layer 117 is closest to the sidewalls 111 and can be in direct contact with the sidewalls 111. The oxide layer 117 can be silicon dioxide or the like. In some embodiments, the oxide layer 117 has a thickness in the range from about 30 nm to about 100 nm. If the oxide layer 117 is too thin, the TSV 109 may not be adequately insulated from the semiconductor substrate 171. If the oxide layer 117 is too thick, it will reduce the width of the TSV 109.

The conformal silicon nitride layer 115 can be a non-oxide dielectric such as silicon nitride or the like or some other dielectric having a distinct composition from the oxide layer 117. The conformal silicon nitride layer 115 is provided to protect the oxide layer 117 during a selective wet etch process that will be described in greater detail below. In some embodiments, the conformal silicon nitride layer 115 has a thickness in the range from about 10 nm to about 500 nm. If the conformal silicon nitride layer 115 is too thin, the oxide layer 117 may be damaged during a process of forming the TSV 109 causing current to leak between the TSV 109 and the semiconductor substrate 171. If the conformal silicon nitride layer 115 is too thick, it will reduce the width of the TSV 109.

The nonconformal silicon nitride layer 105 can be a non-oxide dielectric such as silicon nitride or the like or some other dielectric having a distinct composition from the oxide layer 117. The nonconformal silicon nitride layer 105 is provided to produce the overhang 101. The overhang 101 protects other portions of the TSV liner 107 during an anisotropic dry etch process that will be described in greater detail below. The width of the overhang 101 is greater than a variation in the width of the TSV 109 between the front side 167 and the back side 175. In some embodiments, the width of the overhang (the maximum thickness of the nonconformal silicon nitride layer 105 along the sides of the TSV 109) is in the range from about 40 nm to about 140nm. If the nonconformal silicon nitride layer 105 is too thin, parts of the TSV liner 107 may be damaged during a process of forming the TSV 109 and cause current to leak between the TSV 109 and the semiconductor substrate 171. If the nonconformal silicon nitride layer 105 is too thick, the conductivity of the TSV 109 may be excessively reduced by narrowing at one or both ends.

The conformal silicon nitride layer 115 and the nonconformal silicon nitride layer 105 have been illustrated as two separate layers, however, they may be indistinguishable. The conformal silicon nitride layer 115 may be formed before the nonconformal silicon nitride layer 105 or the nonconformal silicon nitride layer 105 may be formed before the conformal silicon nitride layer 115. Processes of forming the conformal silicon nitride layer 115 and the nonconformal silicon nitride layer 105 may be blended together.

A combined silicon nitride layer 103, which includes the conformal silicon nitride layer 115 and nonconformal silicon nitride layer 105, has a uniform thickness over a portion 121 of the TSV liner 107 proximate the front side 167. The uniform thickness corresponds to the conformal silicon nitride layer 115. The combined silicon nitride layer 103 thickens at one end to provide the overhang 101. In some embodiments, a ratio between a maximum thickness of the combined silicon nitride layer 103 and a minimum thickness of the combined silicon nitride layer 103 is in the range from about 2.5 to about 9.

The conformal silicon nitride layer 115 and the nonconformal silicon nitride layer 105 are described as “silicon nitride” layers because they are typically silicon nitride and the present description is easier to understand if they are described as such. However, it will be appreciated that other dielectrics may be substituted for the silicon nitride provided they can be used in a functionally comparable manner to that in which silicon nitride is used in a process of the present disclosure.

The TSV 109 extends through a back side dielectric structure 183 above the back side 175. The back side dielectric structure 183 includes a passivation layer 179 and extensions of the TSV liner 107 resulting from deposition of its component layers (the oxide layer 117 and the combined silicon nitride layer 103) over the back side 175. The passivation layer 179 may be an oxide such as undoped silicate glass (USG) or the like. In some embodiments, the passivation layer 179 has a thickness in the range from about 100 nm to about 500 nm.

The TSV 109 extends through one or more oxide layers immediately before reaching a contact pad 124 disposed in a metallization layer 149 over the front side 167. In the IC device 100, the oxide layers include a bottom portion of the oxide layer 117 and a second ILD layer 151. The sidewalls 126 of the TSV 109 have a much shallower slope as the TSV 109 extends through these oxide layers as compared to areas where the TSV 109 is extending through the semiconductor substrate 171. The slope is much shallower due to the wet etch process used to etch through these oxide layers. The slope causes the TSV to become narrower.

The TSV 109 extends through a front side dielectric structure 122 disposed between the front side 167 and the metallization layer 149 that includes the contact pad 124. In some embodiments, the front side dielectric structure 122 includes a plurality of oxide layers separated by etch stop layers. In some embodiments, the front side dielectric structure 122 includes a plurality of etch stop layers. The oxide and etch stop layers may be associated with structures formed during FEOL processing such as the fin field effect transistor (FinFET) 133, the contact plugs 137, and the vias 135 that couple the contact plugs 137 to wires 136 in the metallization layer 149.

In the IC device 100, the front side dielectric structure 122 can include a first oxide layer 163, a bottom contact etch stop layer 161, a second oxide layer 159, a middle contact etch stop layer 157, a first interlevel dielectric (ILD) layer 155, a first via etch stop layer 153, and the second ILD layer 151. Other film schemes may be used, depending on the process.

The first oxide layer 163 may be one or more layers of silicon dioxide, a low-k dielectric, or the like and has the same height as the semiconductor fin 169. In some embodiments, the first oxide layer 163 has a thickness in the range from about 30 nm to about 90 nm. The thickness is determined by the height as the semiconductor fin 169, which relates to requirements for the FinFETs 133.

The bottom contact etch stop layer 161 provides an etch stop for landing contact plugs 137 on source/drain regions 170. The bottom contact etch stop layer 161 can be silicon carbide, silicon carbide nitride, silicon nitride, the like, or any other suitable material. In some embodiments, the bottom contact etch stop layer 161 is from about 4 to about 8 nm thick.

The second oxide layer 159 is silicon dioxide, a low-k dielectric, or the like and has the same height as the gate electrode 134. In some embodiments, the second oxide layer 159 has a thickness in the range from about 30 nm to about 90 nm. The thickness is determined by the height of the gate electrode 134, which relates to requirements for the FinFETs 133.

The middle contact etch stop layer 157 provides an etch stop for landing contact plugs 137 on the gate electrode 134. The middle contact etch stop layer 157 can be silicon carbide, silicon carbide nitride, silicon nitride, the like, or any other suitable material. In some embodiments, the bottom contact etch stop layer 161 is from about 2 to about 5 nm thick.

The first ILD layer 155 is silicon dioxide, a low-k dielectric, or the like. In some embodiments, the first ILD layer 155 is a low-k dielectric layer. In some embodiments, the first ILD layer 155 has a thickness in the range from about 10 nm to about 30 nm.

The first via etch stop layer 153 provides an etch stop for landing the vias 135 on the contact plugs 137. The first via etch stop layer 153 also provides an etch stop for etching an opening in which the TSV 109 is formed. Accordingly, in some embodiments the first via etch stop layer 153 is thicker than any of the other etch stop layers in the front side dielectric structure 122. In some embodiments, the first via etch stop layer 153 has a thickness in the range from about 8 nm to about 20 nm.

The second ILD layer 151 is silicon dioxide, a low-k dielectric, or the like. In some embodiments, the second ILD layer 151 is a low-k dielectric layer. In some embodiments, the second ILD layer 151 has a thickness in the range from about 10 nm to about 30 nm.

In a process according to the present disclosure, a hole etched through the semiconductor substrate 171 for the TSV 109 is extended through the front side dielectric structure 122 and stops on the last oxide layer after breaking through the last etch stop layer. The “last etch stop layer” and the “last oxide layer” are the last ones deposited when forming the front side dielectric structure 122 and the last ones encountered when etching through the front side dielectric structure 122 starting from the back side 175. In the illustrated example, the last etch stop layer is the first via etch stop layer 153 and the last oxide layer is the second ILD layer 151.

As a result of the process, in some embodiments the TSV liner 107 extends through the first via etch stop layer 153 (the last etch stop layer) and extends horizontally to line an upper surface of the second ILD layer 151 (the last oxide layer). A portion of the TSV liner 107 corresponding to the conformal silicon nitride layer 115 extends horizontally as far as the overhang 101. The oxide layer 117 is etched by a selective isotropic etch process so that it becomes recessed relative to the conformal silicon nitride layer 115. This results in the conformal silicon nitride layer 115 developing the protrusion 129, which extends inward of the oxide layer 117 into the TSV 109 proximate the front side 167.

The TSV 109 extends through the second ILD layer 151 to the contact pad 124 disposed with the metallization layer 149. The metallization layer 149 is the first metallization layer in the BEOL interconnect structure 145. The BEOL structure includes wires 143 disposed within a BEOL dielectric structure 147. The metallization layer 149 is one of a plurality of metallization layers containing wires 143. The metallization layers are interleaved with via layers. The via layer contain vias (not shown) that interconnect wires 143 in adjacent metallization layers.

The wires 143 and the vias can be a metal such as copper, ruthenium, tungsten, aluminum, cobalt, gold, nickel, combinations thereof, the like, or any other suitable conductive material. In some embodiments, the wires 143 comprise copper. Copper has low resistivity and is the dominant choice for advanced semiconductor processing nodes. Copper wires are typically lined with a diffusion barrier. The diffusion barrier can be tantalum, tantalum nitride, titanium nitride, ruthenium, the like, or any other suitable material.

The BEOL dielectric structure 147 can comprise silicon dioxide, a low-k dielectric, or an extremely low-k dielectric. A low-κ dielectric is one having a smaller dielectric constant than silicon dioxide. Silicon dioxide has a dielectric constant of about 3.9. Examples of low-κ dielectrics include organosilicate glasses (OSG) such as carbon-doped silicon dioxide, fluorine-doped silicon dioxide (otherwise referred to as fluorinated silica glass (FSG), organic polymer low-κ dielectrics, and porous silicate glass. An extremely low-κ dielectric is a material having a dielectric constant of about 2.1 or less. An extremely low-κ dielectric material is generally a low-κ dielectric material formed into a porous structure. Porosity reduces the effective dielectric constant.

In some embodiments, the BEOL dielectric structure 147, including the dielectric structure 123 within the metallization layer 149, includes an extremely low-κ dielectric. Extremely low-κ dielectrics are used in the BEOL interconnect structures for advanced processing nodes to reduce capacitive coupling and lower RC delays. It should be appreciated that extremely low-κ dielectrics are generally much more susceptible to etching than silicon dioxide or merely low-k dielectrics and that this adds to the challenge of using a slotted contact pad for a TSV.

The BEOL dielectric structure 147 also includes etch stop layers. These include via etch stop layers disposed on each metallization layer. One such etch stop layer, the second via etch stop layer 148, is illustrated in FIG. 1. These etch stop layers can be silicon carbide, silicon carbide nitride, silicon nitride, the like, or any other suitable material.

The contact pad 124 is slotted in the sense that it is composed of wires 127 with gaps 125 between them. The TSV 109 contacts the tops of the wires 127 (from the perspective of FIG. 1) and extends into the gaps 125 to contact the sides of the wires 127. In some embodiments, the TSV 109 extends to the second via etch stop layer 148, but does not extend through the second via etch stop layer 148. This is a consequence of the etch susceptibility of the dielectric structure 123 and the selective etch process used to form the TSV 109 in a process of the present disclosure.

FIG. 1A provides a plan view 110 of the contact pad 124. The TSV 109 just above the contact pad 124 is shown in transparency. The TSV 109 extends over wires 127 and gaps 125. In some embodiments, a ratio between the TSV footprint area corresponding to wires and the TSV footprint area corresponding to gaps is in the range from about 1:2 to about 2:1. In general, the ratio is about 1:1, which is typical for the lower metallization layers in advanced semiconductor processes. The wire density in the contact pad 124 is approximately the same as the wire density used throughout the metallization layer 149 (see FIG. 1).

An array of vias 201 can connect the wires 127 in the contact pad 124 to the wires 143 in the next metallization layer. Providing a plurality of vias 201 for each wire 127 reduces electrical resistance. The wires in the next metallization layer may run perpendicular to the wires 127, whereby all of the wires 127 are electrically coupled together. It will be appreciated that many possible arrangements of the wires 127 and the vias 201 are possible while remaining within the constraints of process requirements.

Returning to FIG. 1, the TSV 109 may comprise multiple layers of conductive materials. In some embodiments, the TSV 109 comprises a conductive core 112 lined with a glue layer 113. The glue layer 113 assures good adhesion and may also provide a diffusion barrier. The glue layer 113 can be, for example, tantalum, tantalum nitride, titanium, titanium nitride, ruthenium, cobalt, the like, or any other suitable material. The glue layer 113 can have a thickness in the range from about 5 nm to about 50 nm.

The conductive core 112 can be any suitable material. In some embodiments, the conductive core 112 is metal. In some embodiments, the conductive core 112 is copper, aluminum, tungsten, cobalt, ruthenium, an alloy or combination thereof, or the like. In some embodiments, the conductive core 112 is copper or the like. Copper is most commonly used in advanced semiconductor process nodes due to its low resistivity, high current carrying capacity, and process compatibility.

The semiconductor substrate 171 can be a monocrystalline semiconductor. The semiconductor may be silicon (Si), a group III-V semiconductor (e.g., GaAs) or some other binary semiconductor, a tertiary semiconductor (e.g., AlGaAs), a higher order semiconductor, the like, or any other suitable semiconductor. In some embodiments, the semiconductor is silicon (Si) or the like, which is the type most commonly used in advanced semiconductor processing. The semiconductor substrate 171 is made thin to limit the length and aspect ratio of the TSV 109. In some embodiments, the semiconductor substrate 171 has a thickness of about 5 μm or less. In some embodiments, the thickness is about 3 μm or less.

At least to provide mechanical strength, but potentially also to provide additional functionality, the semiconductor substrate 171 is attached to a second substrate 139 through a bonding layer 141. The second substrate 139 may be another semiconductor substrate, or just a carrier substrate. In some embodiments, the bonding layer 141 uses metal-to-metal and dielectric-to-dielectric bonding, which facilitates providing a high connection density suitable for advanced semiconductor process nodes.

Additional structures may be formed above the ones shown in FIG. 1. These may include a redistribution layer, bond pads, bonding layers, or additional semiconductor chips. TSVs 109 are suitable for 3D architectures in which many semiconductor dies are vertically stacked.

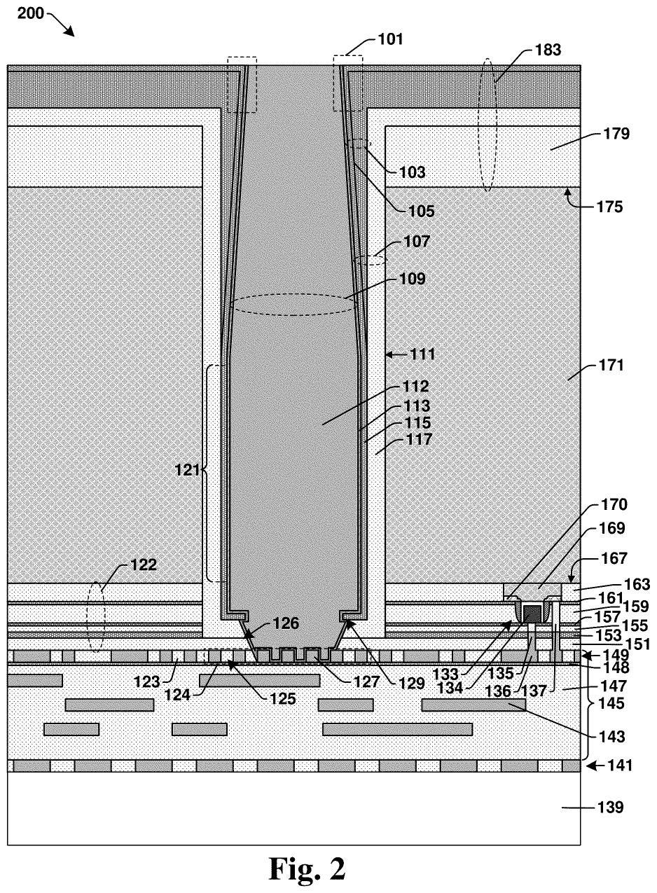

FIG. 2 illustrates a cross-sectional view of an IC device 200 in accordance with another embodiment. The IC device 200 can be the same as the IC device 100 of FIG. 1 except that the conformal silicon nitride layer 115 is disposed over the nonconformal silicon nitride layer 105 rather than the other way around. It may be difficult or impossible to identify a boundary between the conformal silicon nitride layer 115 and the nonconformal silicon nitride layer 105. Accordingly, the IC device 200 may be indistinguishable from the IC device 100.

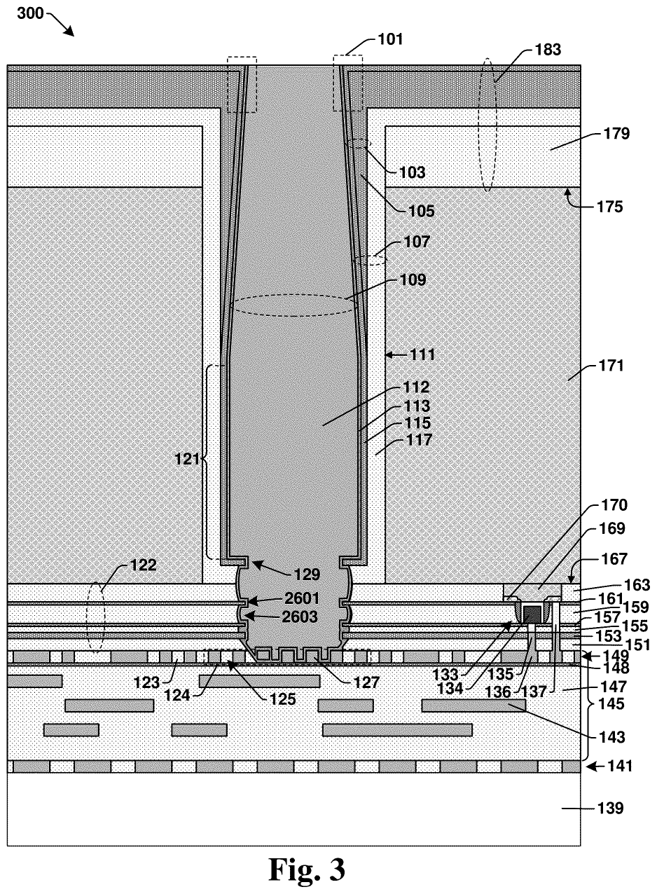

FIG. 3 illustrates a cross-sectional view of an IC device 300 in accordance with another embodiment. The IC device 300 is like the IC device 100 except for differences in an area proximate the front side 167 resulting from a difference in the process used to form the TSV 109. This difference results in the TSV liner 107 extending horizontally at a higher point than in the IC device 100 of FIG. 1. In the IC device 300, the TSV liner 107 extends horizontally to line an upper surface of the first oxide layer 163. The protrusion 129 is higher (further from the contact pad 124) than in the IC device 100 and additional protrusions 2601 are formed by the lower contact etch stop layer 161, the middle contact etch stop layer 157, and the first via etch stop layer 153. The oxide layers have indentations 2603 between the etch stop layers. The indentations 2603 result from a selective wet etch process used to break through the second ILD layer 151 to expose the contact pad 124 without damaging it.

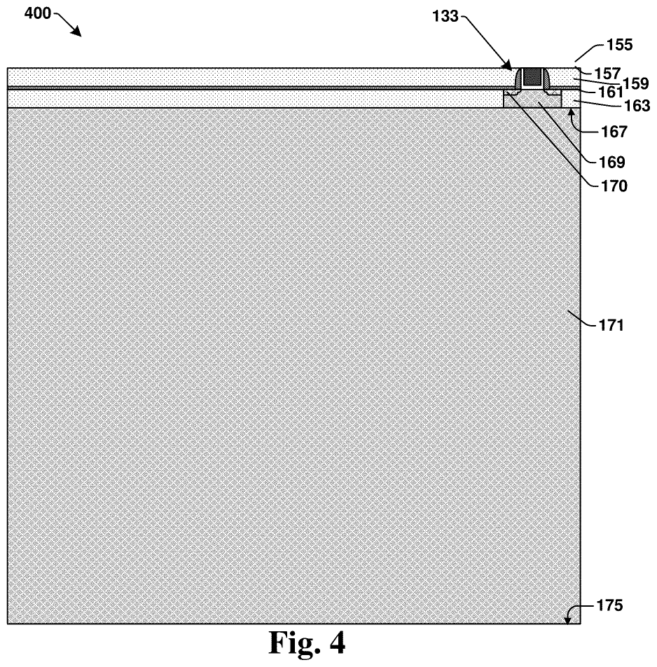

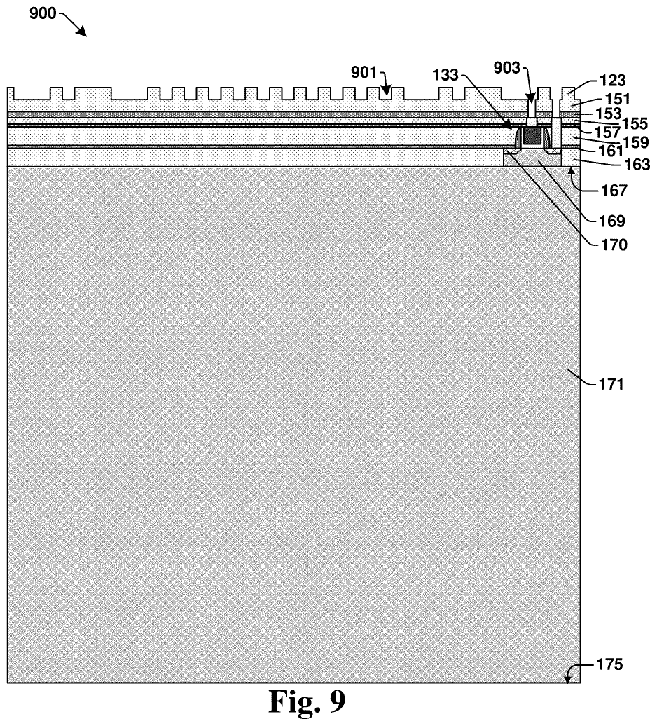

FIGS. 4-22 provide a series of cross-sectional views 400-2200 that illustrate an IC device according to the present disclosure at various stages of manufacture according to a process of the present disclosure. Although FIGS. 4-22 are described in relation to a series of acts, it will be appreciated that the order of the acts may in some cases be altered and that this series of acts are applicable to structures other than the ones illustrated. In some embodiments, some of these acts may be omitted in whole or in part. Furthermore, FIGS. 4-22 are described in relation to a series of acts, it will be appreciated that the structures shown in FIGS. 4-22 are not limited to a method of manufacture but rather may stand alone as structures separate from the method.

FIG. 4 illustrates a cross-sectional view 400 of the semiconductor substrate 171 at the conclusion of FEOL processing. The semiconductor substrate 171 may be a monocrystalline substrate, a silicon-on-insulator substrate, or any other type of substrate. At least an uppermost layer of the semiconductor substrate 171 is a semiconductor.

FEOL processing forms isolation structures (not shown), well implants (not shown), and various semiconductor devices, in and on the semiconductor substrate 171. The semiconductor devices typically include transistors, and may include diodes, capacitors, memory cells, thyristors, resistors, or the like. In some embodiments, the transistors are FinFETs 133 or gate all around (GAA) transistors, which are the types of transistors used in advanced semiconductor processing nodes. GAA transistors can have nanosheet or nanowire channel structures.

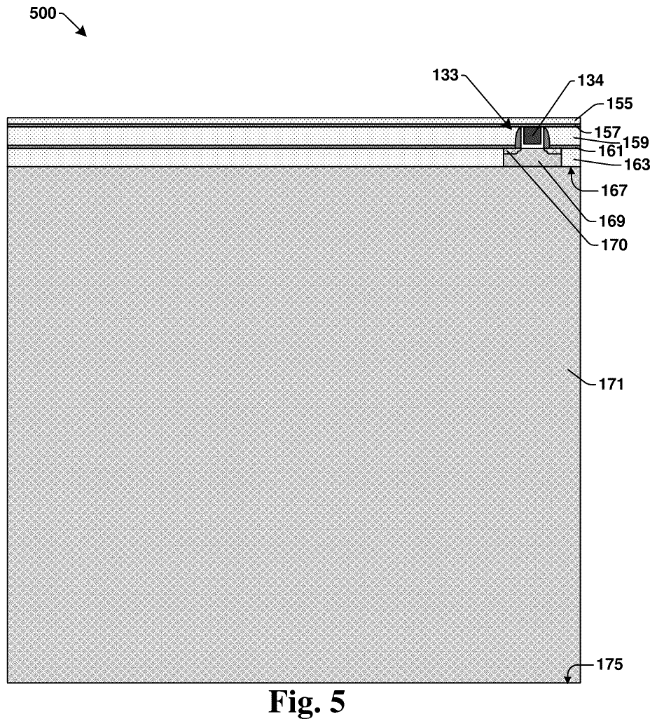

As shown by the cross-sectional view 500 of FIG. 5, the middle contact etch stop layer 157 and the first interlevel dielectric (ILD) layer 155 are deposited over the layer in which the FinFET 133 is disposed. These layers can be deposited by atomic layer deposition (ALD), chemical vapor deposition (CVD), physical vapor deposition (PVD), the like, or any other suitable processes.

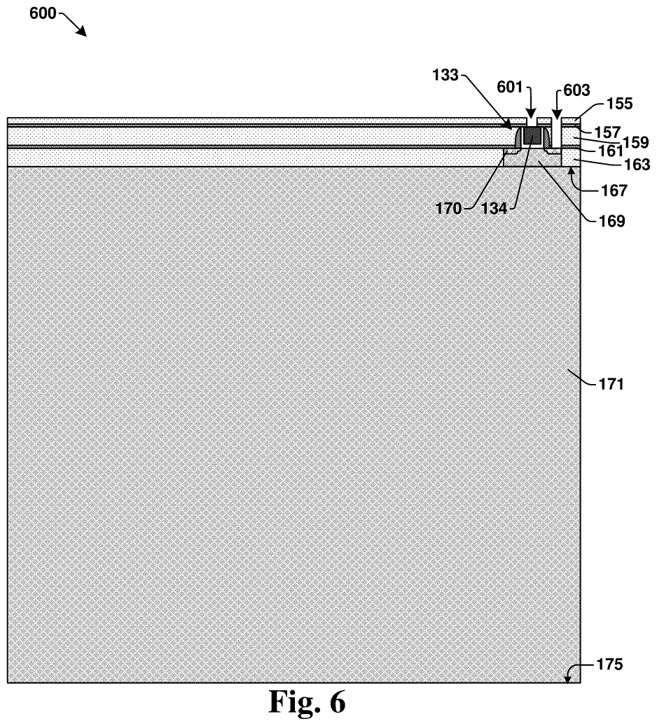

As shown by the cross-sectional view 600 of FIG. 6 holes 601 are formed to expose the gate electrodes 134 and holes 603 are formed to expose the source/drain regions 170 of the FinFETs 133. These holes may be formed using a plurality of masking and etching operations. The bottom contact etch stop layer 161 provides an etch stop for the holes 603 and the middle contact etch stop layer 157 provides an etch stop for the holes 601. The masks used in this process, and in other processes of the present disclosure, can comprise photoresists, hard masks, or the like and can be patterned by photolithography, ion beam lithography, the like, or some other suitable process. The etch processes can be dry etch processes such as plasma etching, the like, or any other suitable etch processes.

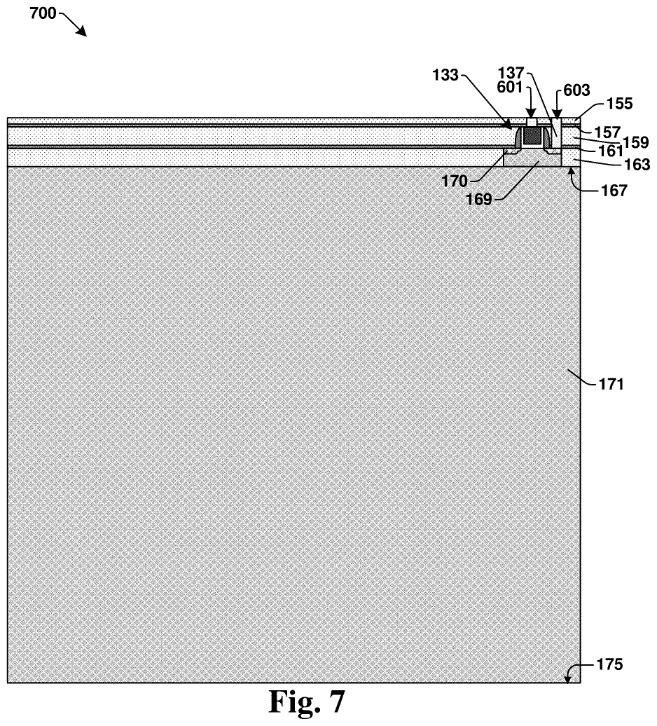

As shown by the cross-sectional view 700 of FIG. 7, the holes 601 and 603 are filled with conductive material to provide contact plugs 137. The contact plugs 137 are often of a metal that is distinct metal from the metal used in the BEOL interconnect structure 145 (see FIG. 1). The contact plugs 137 can be, for example, tungsten, cobalt, cobalt silicide, nickel, nickel silicide, an alloy thereof, or the like. The contact plug of formation can include deposition followed by chemical mechanical polishing (CMP) to remove excess metal. The deposition process can be ALD, CVD, PVD, electroplating, electroless plating, the like, or any other suitable process. The processing illustrated by FIGS. 5-7 is middle-of-line (MOL) processing.

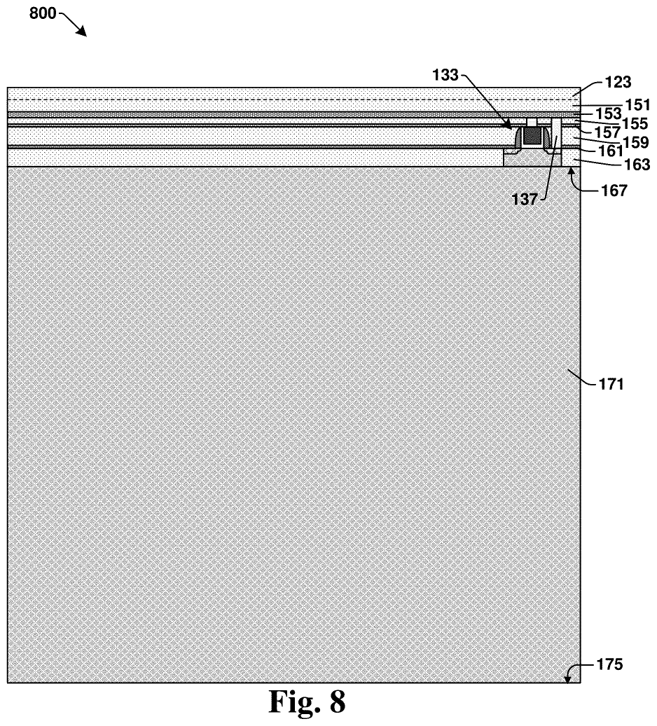

The cross-sectional view 800 of FIG. 8 shows the beginning of BEOL processing. As shown by the cross-sectional view 800 of FIG. 8, the first step in BEOL processing can be deposition of the first via etch stop layer 153, the second ILD layer 151, and the dielectric structure 123. The second ILD layer 151, and the dielectric structure 123 may be deposited as a single layer, which can be a low-k or extremely low-k dielectric layer. The deposition processes can be ALD, CVD, PVD, the like, or any other suitable processes.

As shown by the cross-sectional view 900, holes 903 and trenches 901 are formed in the second ILD layer 151 and the dielectric structure 123. The holes 903 and the trenches 901 may be formed using a plurality of masking and etching operations. The first via etch stop layer 153 provides an etch stop for etching the holes 903.

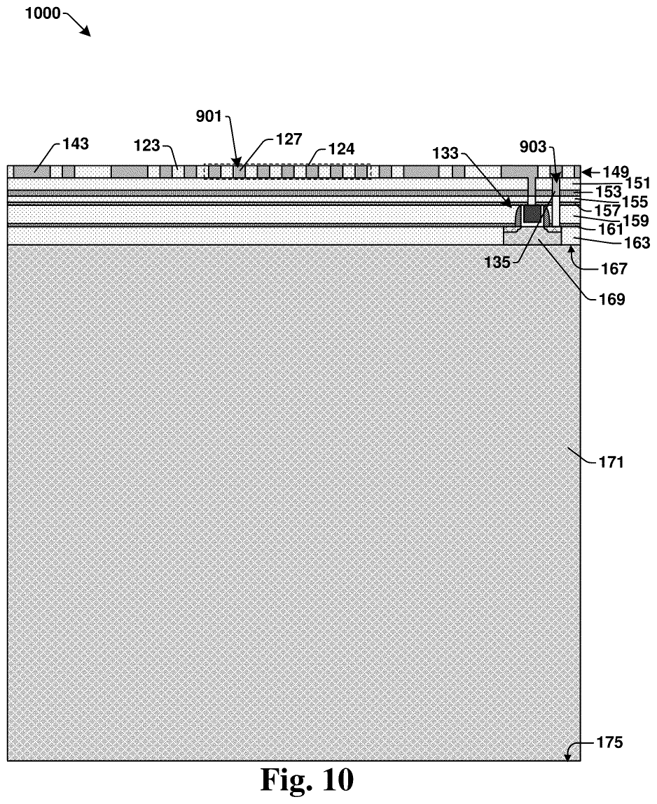

As shown by the cross-sectional view 1000 of FIG. 10, metal is deposited to fill the holes 903 and the trenches 901, creating the vias 135 and the wires 143 respectively. The wires 143 include the wires 127 that make up the contact pad 124. This step completes the formation of the metallization layer 149. The deposition process can be ALD, CVD, PVD, electroplating, electroless plating, the like, or any other suitable process. Excess metal can be removed by CMP. The process shown in by the cross-sectional views 800-100 of FIG. 8-10 is an example of a dual damascene process.

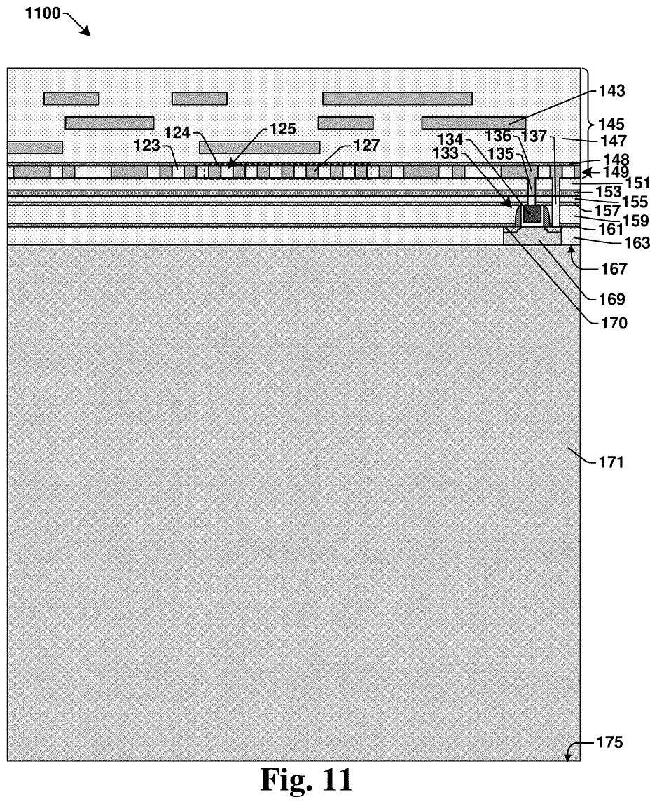

As shown by the cross-sectional view 1100 of FIG. 11, additional metallization and via layers are deposited to complete the formation of the BEOL interconnect structure 145. These layers may be formed by damascene or dual damascene processes. Additional etch stop layers of which only the second via etch stop layer 148 is shown are deposited after each metallization layer.

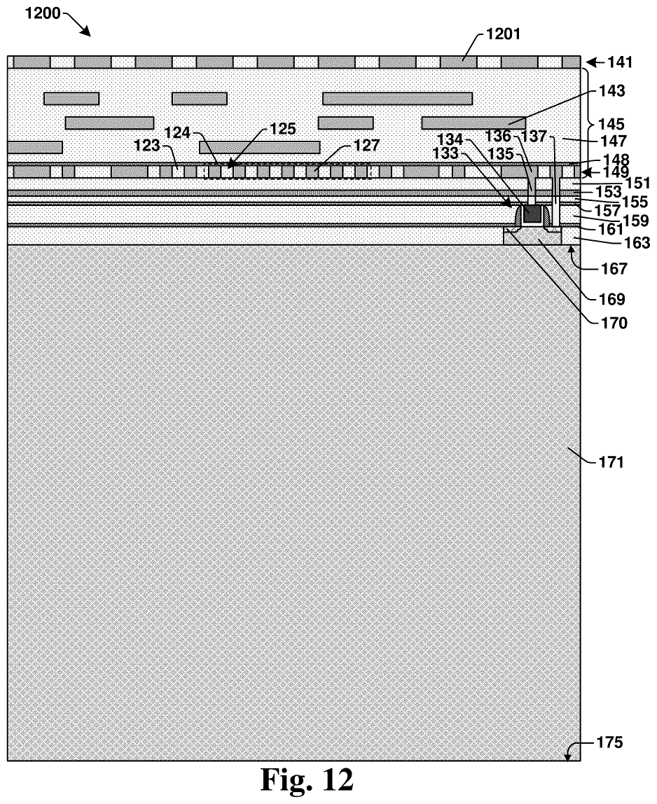

As shown by the cross-sectional view 1200 of FIG. 12, a bonding layer 141 is deposited over the BEOL interconnect structure 145. The bonding layer 141 can include bond pads 1201.

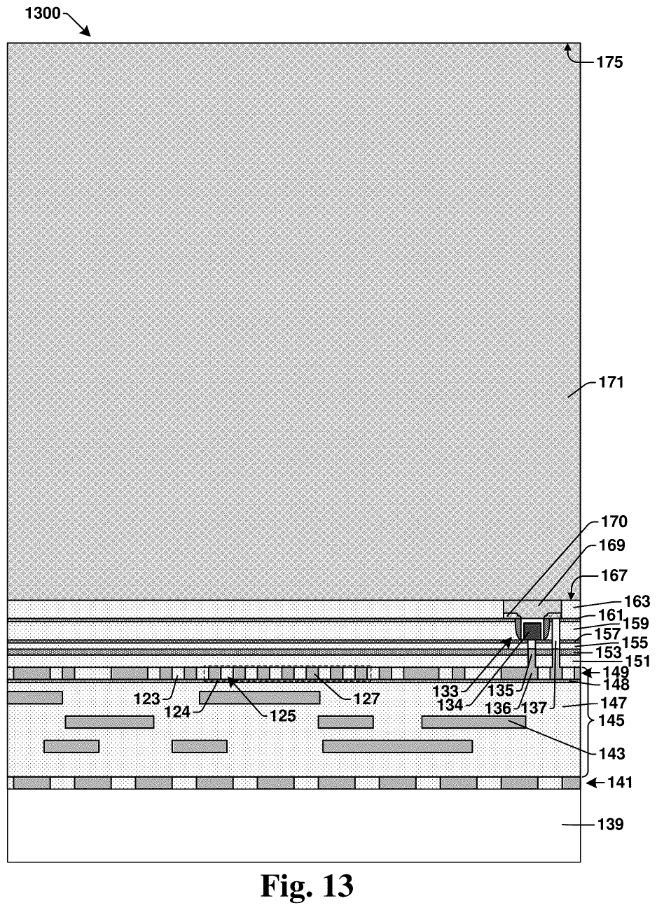

As shown by the cross-sectional view 1300 of FIG. 13, the semiconductor substrate 171 can be inverted and bonded to the second substrate 139. The bonding process can include metal-to-metal bonding, dielectric-to-dielectric bonding, or both metal-to-metal and dielectric-to-dielectric bonding. The later process is commonly used in advance semiconductor process nodes.

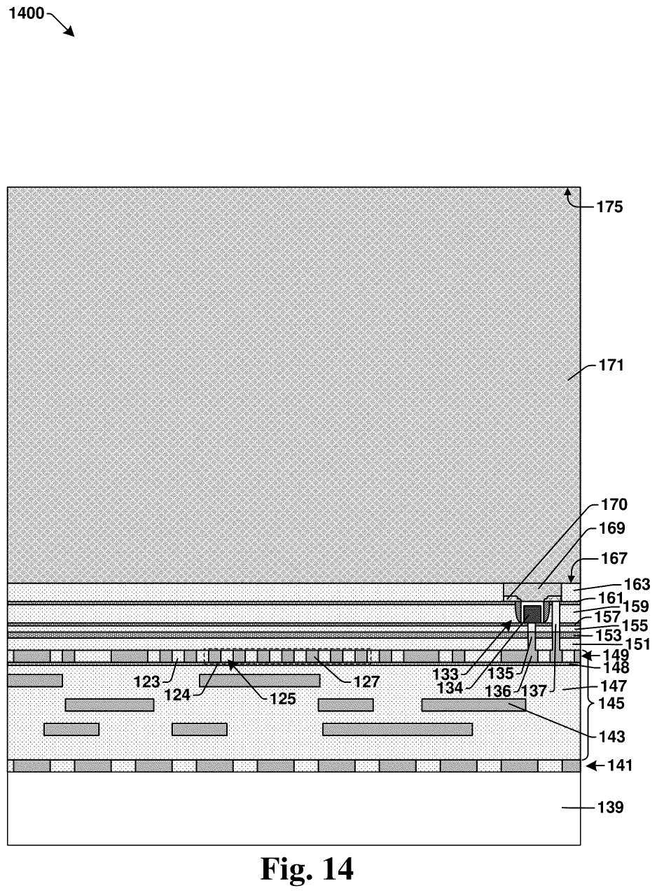

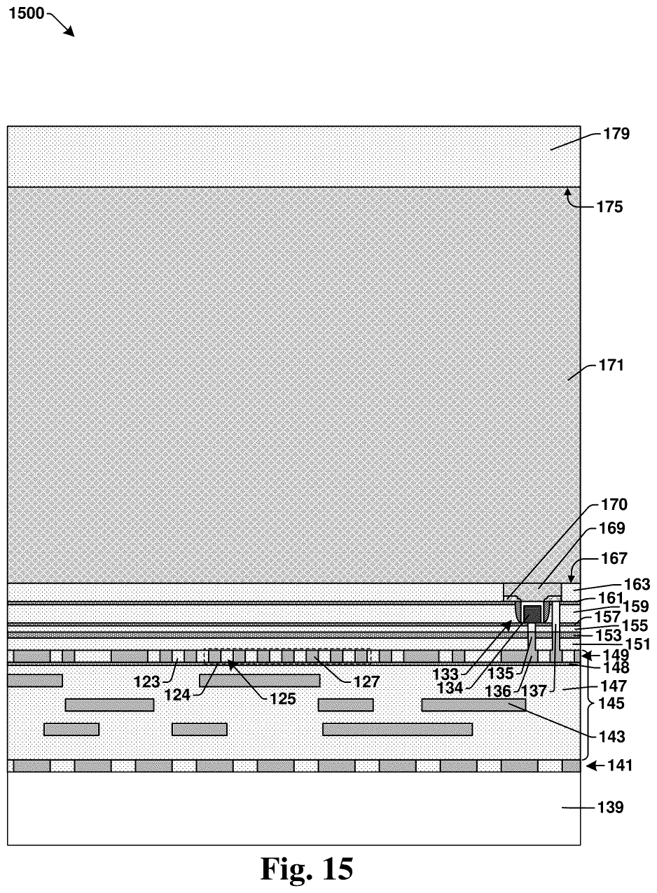

As shown by the cross-sectional view 1400 of FIG. 14, after bonding, the semiconductor substrate 171 is thinned from the back side 175. The thinning process can include one or more of grinding, CMP, etching, or the like. As shown by the cross-sectional view 1500 of FIG. 15, after thinning, the passivation layer 179 is deposited on the back side 175. The passivation layer 179 may be deposited by CVD, the like, or any other suitable process.

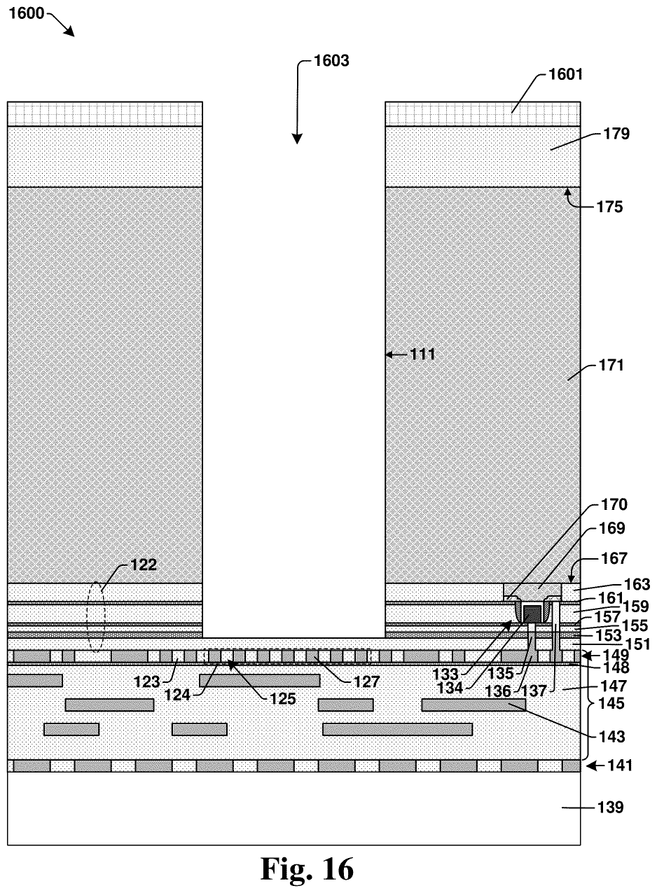

As shown by the cross-sectional view 1600 of FIG. 16, a mask 1601 is formed over the back side 175 and used to etch the TSV hole 1603. The TSV hole 1603 extends through the passivation layer 179, the semiconductor substrate 171, and all the layers of the front side dielectric structure 122 except for the last oxide layer, which is the second ILD layer 151. An anisotropic dry etch process such as reactive ion etching (REI) with substrate bias may be used to etch through the semiconductor substrate 171. Etch process conditions may be varied to extend the TSV hole 1603 through the various etch stop and oxide layers of the front side dielectric structure 122. The first via etch stop layer 153 is the last etch stop layer encountered, and the last phase of etching breaks through this layer.

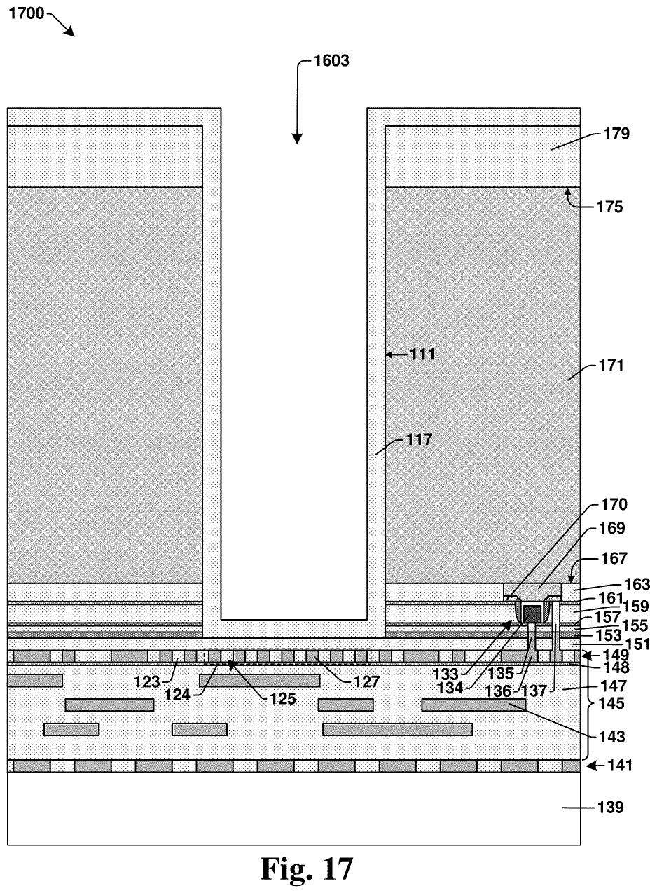

As shown by the cross-sectional view 1700 of FIG. 17 a deposition process can be used to line the TSV hole 1603 with the oxide layer 117. The deposition process can be ALD, CVD, the like, or any other suitable process.

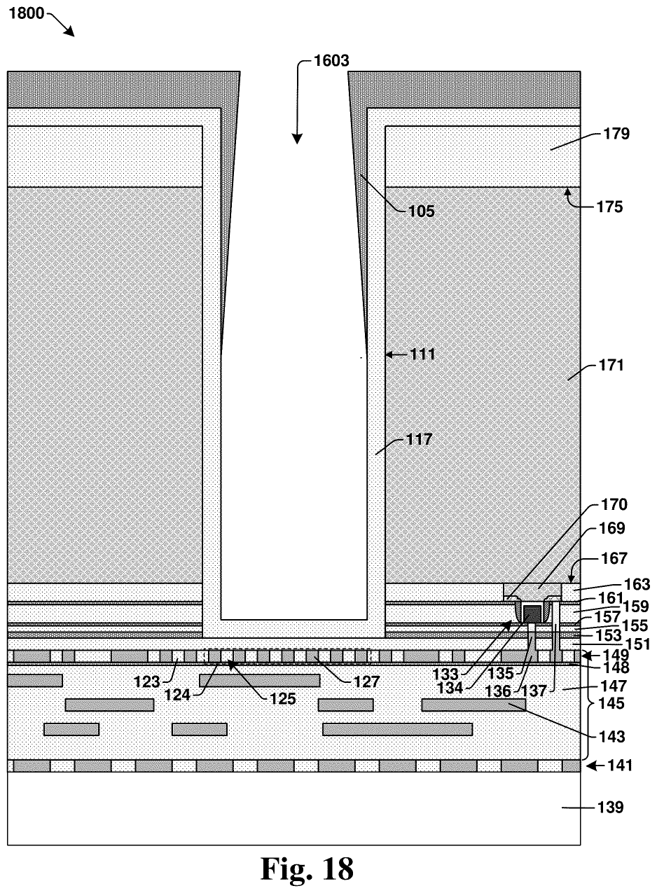

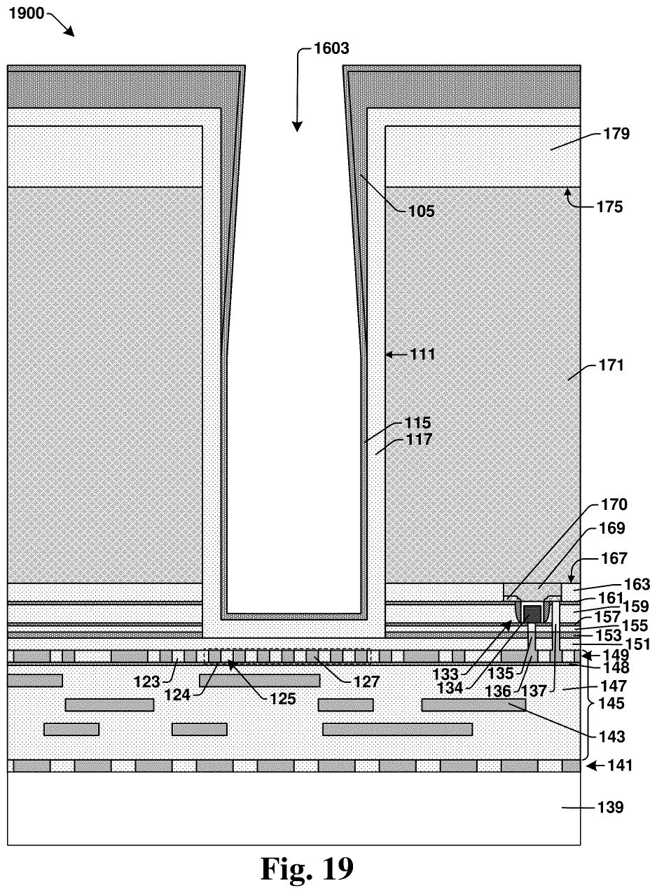

As shown by the cross-sectional view 1800 and 1900 of FIGS. 18 and 19 the conformal silicon nitride layer 115 and the nonconformal silicon nitride layer 105 are deposited over the oxide layer 117. The conformal silicon nitride layer 115 can be deposited by CVD, PVD, ALD, the like, or any other suitable process. The nonconformal silicon nitride layer 115 can be deposited by CVD, PVD, the like, or any other suitable process.

In some embodiments, both layers are deposited by PECVD. The precursors can include any of silane, disilane, trysilylamine, hexachlorodisilane, ammonia, nitrogen, hydrogen, the like, or any other suitable gases. A relatively low substrate bias can be used to provide the nonconformal silicon nitride layer 105. A higher substrate bias can be used to provide the conformal silicon nitride layer 115.

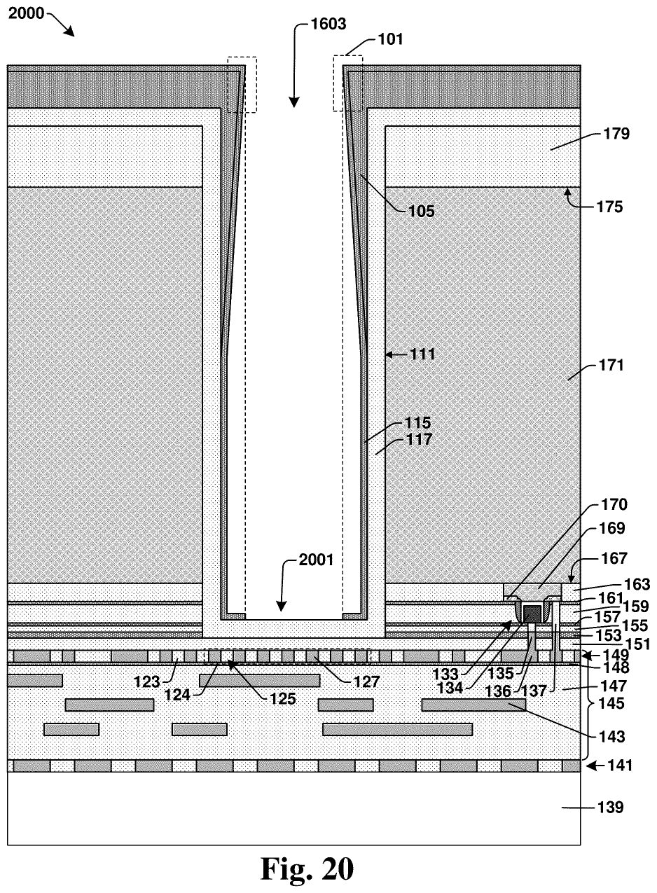

As shown by the cross-sectional view 2000 of FIG. 20, an anisotropic dry etch process can be used to etch an opening 2001 through the conformal silicon nitride layer 115 at the bottom of the TSV hole 1603. Although not shown by the illustration, this etch process may remove some of the silicon nitride over the back side 175, however, the overhang 101 prevents the conformal silicon nitride layer 115 from being removed from the sides of the TSV hole 1603. The opening 2001 forms in alignment with the overhang 101. The etch process may be selective for removing silicon nitride. Alternatively, the dry etch process timing may be controlled to prevent breaking through the last oxide layers at the bottom of the TSV hole 1603.

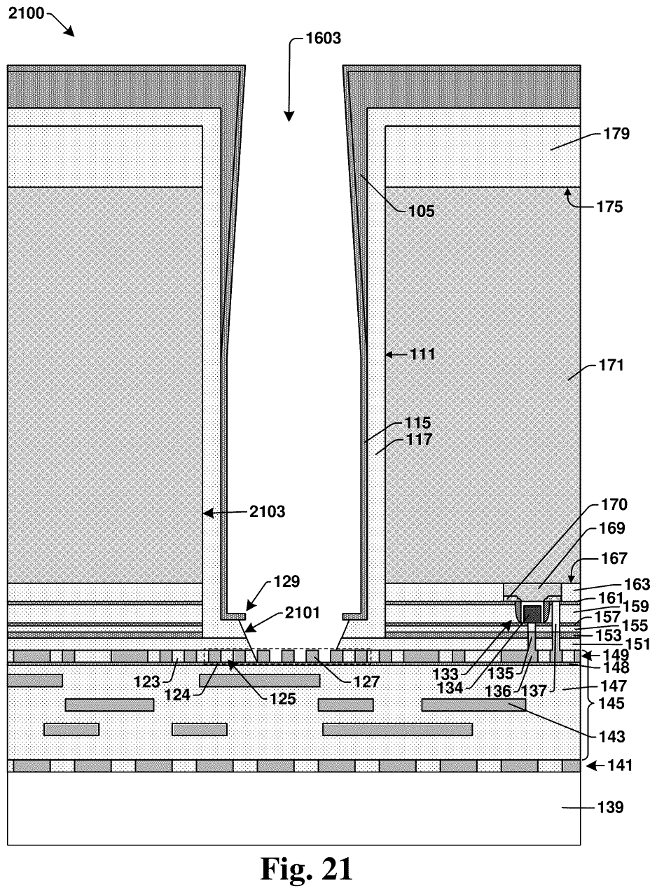

As shown by the cross-sectional view 2100 of FIG. 21, a selective wet etch process is used to etch through the oxide layers exposed at the bottom of the TSV hole 1603, which may include the oxide layer 117, the second ILD layer 151, and some of the dielectric structure 123 around the wires 127. The etch may extend to the second via etch stop layer 148. This etch process exposes the contact pad 124 and can recess the oxide layer 117 beneath the conformal silicon nitride layer 115 resulting in the protrusion 129. The selective wet etch process may use hydrofluoric acid or the like. Hydrofluoric acid provides sufficient etch selectivity to etch through the oxide layers without etching through the conformal silicon nitride layer 115 along the sidewall 111 and will not damage the wires 127 if they are copper or the like.

The sidewalls 2101 formed when the TSV hole 1603 is extended through the oxide layer 117 and the second ILD layer 151 are sloped as a result of being formed by a wet etch process. In some embodiments, the sidewalls 2101 slope at an angle in the range from about 15° to about 60° from vertical. By contrast, the sidewalls 2103 can have a slope less than 15° from vertical.

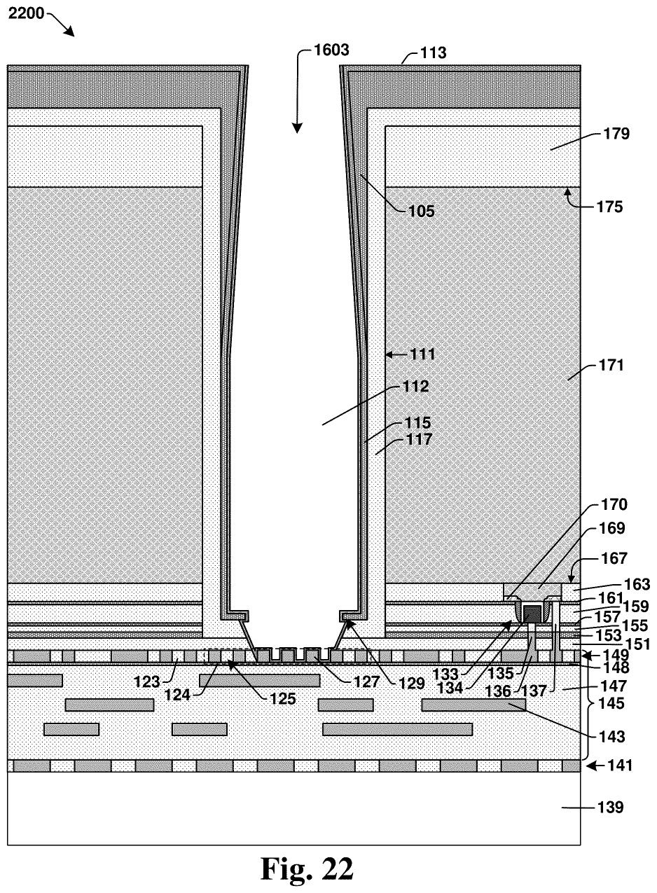

As shown by the cross-sectional view 2200 of FIG. 22, the glue layer 113 can be deposited to line the TSV hole 1603. The deposition process can be ALD, CVD, PVD, the like, or any other suitable process. The TSV hole 1603 can be filled with metal to form the TSV 109 (see FIG. 1). The metal can be deposited by ALD, CVD, PVD, electroplating, electroless plating, the like, or any other suitable process. The glue layer and excess metal can be removed from over the back side 175 by CMP or the like to provide the IC device 100 as shown in FIG. 1.

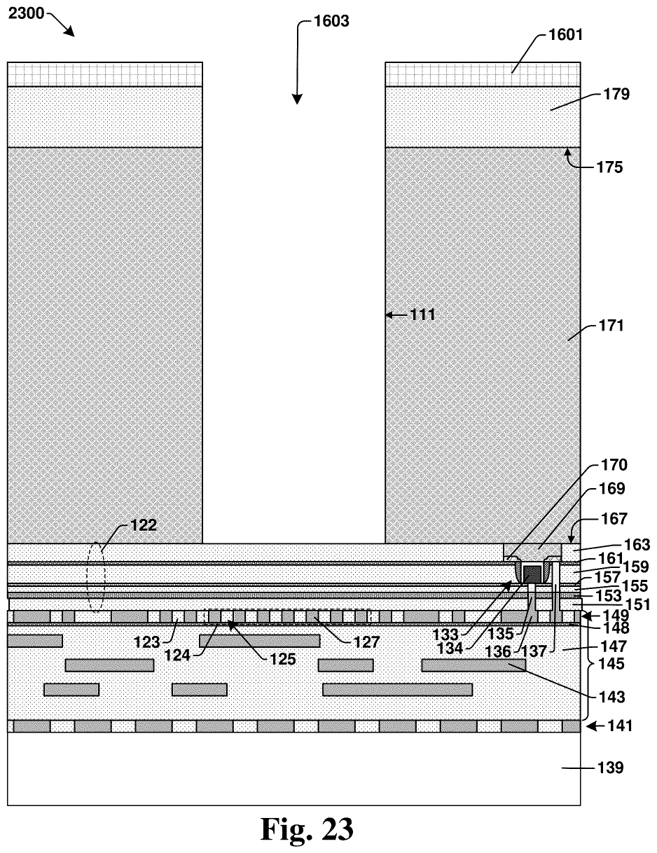

The cross-sectional views 2300-2600 of FIGS. 23 to 26 illustrate a variation on the foregoing process. As shown by the cross-sectional view 2300 of FIG. 23, etching of the TSV hole 1603 using the mask 1601 does not need extended through the first oxide layer 163. As should become clear, etching of the TSV hole 1603 up to the formation of the TSV liner 107 may stop on any one of the layers of the front side dielectric structure 122.

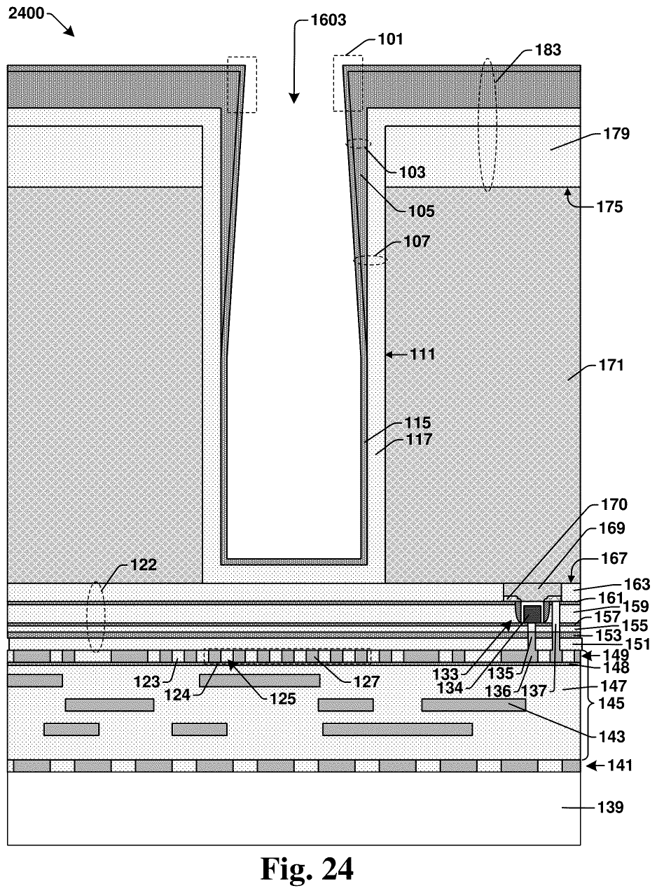

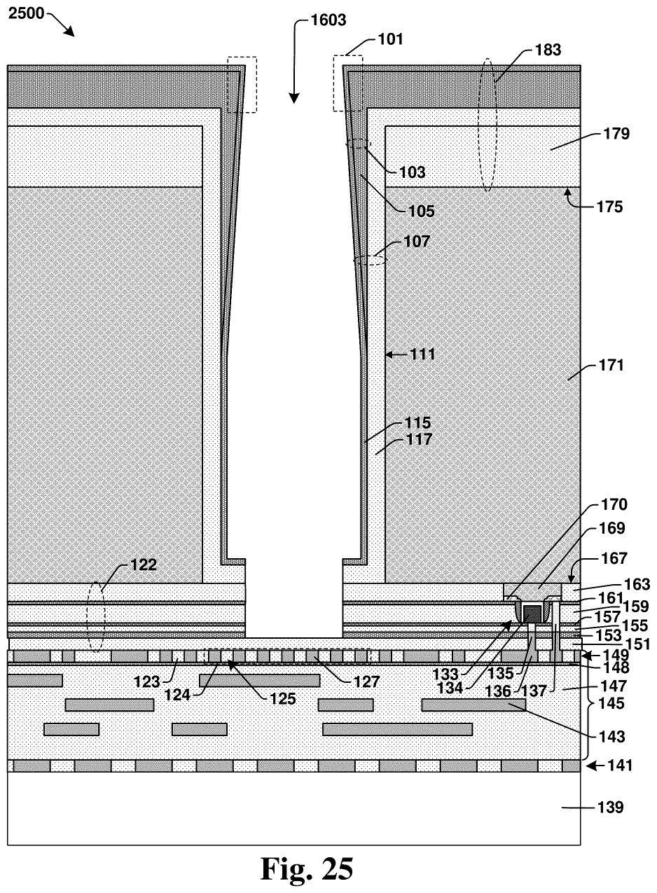

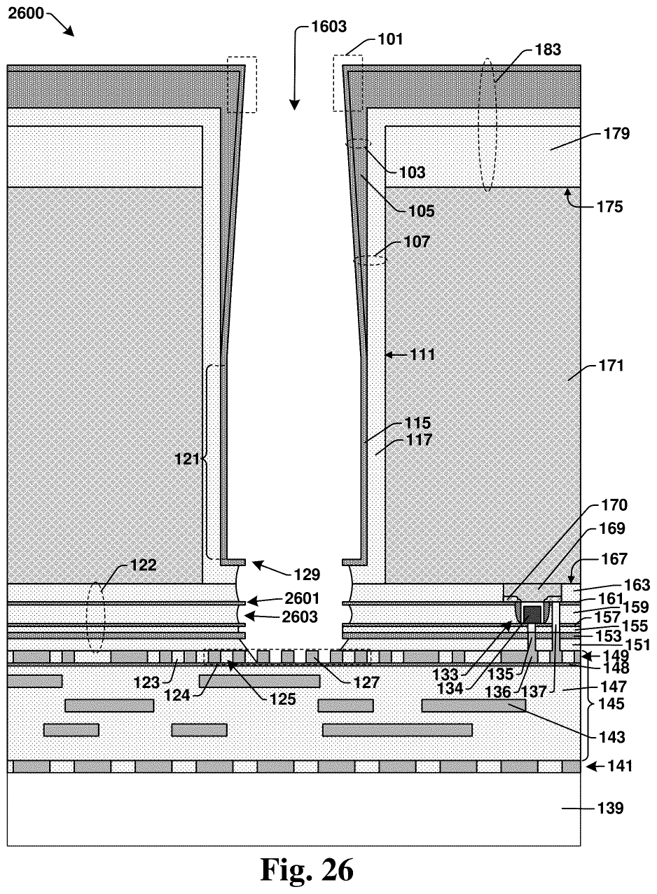

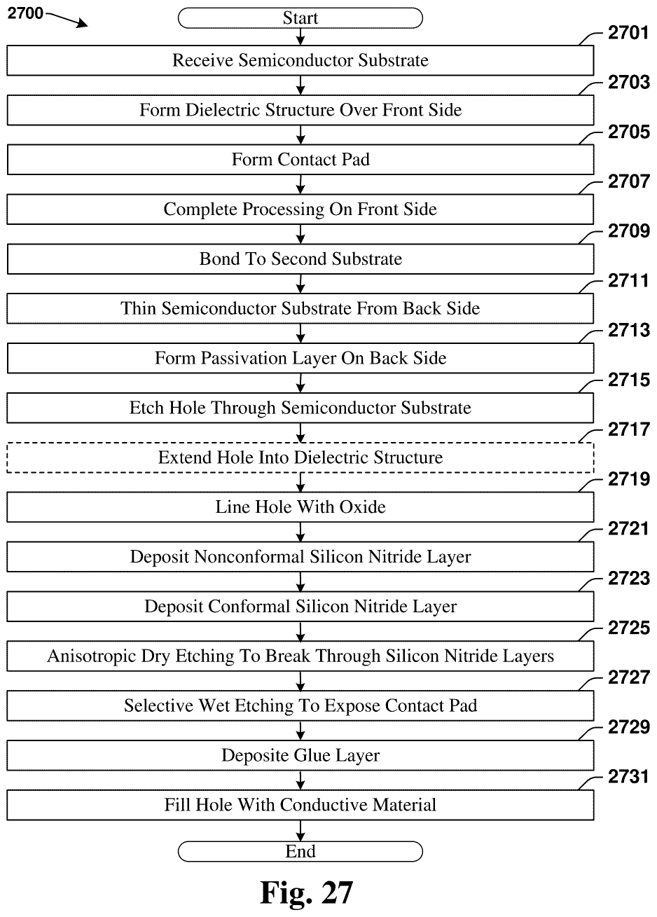

As shown by the cross-sectional view 2400 of FIG. 24, the TSV liner 107 can be formed in the shallower TSV hole 1603. As shown by the cross-sectional view 2500 of FIG. 25, the anisotropic dry etch process may be used to etch through the layers of the front side dielectric structure 122 up to the last oxide layer between the TSV hole 1603 and the contact pad 124, the last oxide being the second ILD layer 151. As shown by the cross-sectional view 2600 of FIG. 26, selective wet etching exposes the contact pad 124 and results in the oxide layers forming indentations 2603 and the etch stop layers forming protrusion 2601. Depositing the glue layer 113 and the conductive core 112 then results in the formation of the IC device 300 of FIG. 3

6499

The method 2700 begins with act 2701, receiving a semiconductor substrate. The substrate may have undergone FEOL processing to form one or more transistors on its front side. The cross-sectional view 400 of FIG. 4 provides an example.

Act 2703 is forming a dielectric structure on the front side. The dielectric structure may be formed in connection with FEOL and MOL processing. The cross-sectional views 500-700 of FIGS. 5 and 7 provide an example.

Act 2705 is forming a contact pad on the front side. The contact pad may be part of the first metallization layer in a BEOL interconnect structure. The cross-sectional views 800-1000 of FIGS. 8 and 10 provide an example.

Act 2707 is completing front side processing. This can include adding a plurality of via layers and metallization layers to complete the formation of the BEOL interconnect structure and can also include forming a bonding structure. The cross-sectional views 1100-1200 of FIGS. 11 and 12 provide an example.

Act 2709 is bonding the semiconductor substrate to a second substrate. The second semiconductor substrate can be a handle substrate or another semiconductor substrate with additional semiconductor devices. The cross-sectional view 1300 of FIG. 13 provides an example.

Act 2711 is thinning the semiconductor substrate from the back side. The cross-sectional view 1400 of FIG. 14 provides an example.

Act 2713 is forming a passivation layer on the back side. The cross-sectional view 1500 of FIG. 15 provides an example.

Act 2715 is etching a hole through the semiconductor substrate. Act 2717 is an optional step of extending the hole into the dielectric structure on the front side. In some embodiments, the hole is extended until only one or more oxide layers remain between the hole and the contact pad. The cross-sectional view 1600 of FIG. 16 provides an example.

Act 2719 is lining the hole with an oxide layer. In some embodiments, the oxide layer is formed using a conformal deposition process. In principle, oxidation of the semiconductor substrate may also or alternatively be used. The cross-sectional view 1700 of FIG. 17 provides an example.

Act 2721 is depositing a nonconformal silicon nitride layer in the hole. The nonconformal silicon nitride layer deposits more thickly around the entrance of the hole, which is proximate the back side, and so forms an overhang that serves as a mask that protects the sides of the hole during subsequent dry etching though layers at the bottom of the hole. The cross-sectional view 1800 of FIG. 18 provides an example of forming this layer.

Act 2723 is depositing a conformal silicon nitride layer over the sides of the hole. The conformal silicon nitride layer protects the oxide layer on the sides of the hole during subsequent wet etch through oxide layers at the bottom of the hole. The cross-sectional view 1900 of FIG. 19 provides an example of forming this layer.

Act 2725 is anisotropic dry etching that etches through the conformal silicon nitride layer at the bottom of the hole and through any etch stop layers of the front side dielectric structure that were not etched through when the hole was extended in act 2717. The anisotropic dry etching continues until only oxide layers remain between the hole and the contact pad. The overhang protects the conformal silicon nitride layer on the sidewalls of the hole during this etch process. The cross-sectional view 2000 of FIG. 20 provides an example.

Act 2727 is selective wet etching to expose the contact pad. The nonconformal silicon nitride layer protects the TSV liner during this etch process. This etching causes some oxide layers to be recessed and some silicon nitride and etch stop layers to protrude. The cross-sectional views 2100 and 2600 of FIGS. 21 and 26 provide examples.

Act 2729 is depositing the glue layer. The cross-sectional view 2100 of FIG. 21 provides an example. Act 2731 is filling the hole through the semiconductor substrate to the contact pad with conductive material to form the TSV. The IC device 100, 200, and 300 of FIGS. 1-3 provide examples of the resulting structure.

Some aspects of the present disclosure relate to an IC device having a TSV extending through a semiconductor substrate to a contact pad on the front side. A BEOL interconnect structure is disposed over the front side. A dielectric liner for the TSV includes an oxide layer extending through the semiconductor substrate, a conformal dielectric layer extending through the semiconductor substrate and disposed between the TSV and the oxide layer, and a nonconformal dielectric layer thickening the dielectric liner proximate the back side of the semiconductor substrate. The conformal dielectric layer and the nonconformal dielectric layer are different in composition from the oxide layer.

In some embodiments, the conformal dielectric layer and the nonconformal dielectric layer are silicon nitride. In some embodiments, the contact pad is slotted. In some embodiments, the contact pad is disposed in a metallization layer of a BEOL interconnect structure. In some embodiments, the contact pad is copper. In some embodiments, a front side dielectric structure comprises a plurality of etch stop layers is disposed between the semiconductor substrate and the contact pad. In some embodiments, the front side dielectric structure comprises a plurality of etch stop layers.

In some embodiments, the conformal dielectric layer protrudes into the TSV. In some embodiments, the TSV extends through an oxide layer between the semiconductor substrate and the contact pad, and the TSV narrows more rapidly as it extends through the oxide layer than it does as it extends through the semiconductor substrate. In some embodiments, the IC device comprises FinFETs or GAA transistors. In some embodiments, the conformal dielectric layer is thinner than the oxide layer.

Some aspects of the present disclosure relate to a method of manufacturing an IC device. The method includes receiving a semiconductor substrate, forming a first dielectric structure over a front side of the substrate, forming an interconnect structure over the first dielectric structure, thinning the semiconductor substrate from the back side, etching a hole through the thinned semiconductor substrate from the back side, lining the hole with an oxide liner layer, depositing a second dielectric layer over the oxide liner layer, performing an anisotropic dry etch, wherein the anisotropic dry etch etches through material at a bottom of the hole including at least the second dielectric layer, performing a selective wet etch to etch through oxide layers at the bottom of the hole and expose the contact pad, and forming a TSV by filling the hole with a conductive material. The first dielectric structure comprises a stack of layers including at least an etch stop layer and a last oxide layer. The interconnect structure comprises a second dielectric structure and a metallization layer comprising one or more metal lines within the second dielectric structure. The metallization layer includes the contact pad. The second dielectric layer covers the oxide liner layer and thickens near the second side to form an overhang. The anisotropic dry etch continues until only oxide layers including the last oxide layer remain between the hole and the contact pad. The wet etch is selective for the last oxide layer relative to the second dielectric layer.

In some embodiments, the second dielectric layer is silicon nitride. In some embodiments, performing the selective wet etch comprises etching with hydrofluoric acid. In some embodiments, prior to lining the hole with the oxide liner layer, the hole is extended to the last oxide layer. In some embodiments, depositing the second dielectric layer over the oxide liner layer comprises a conformal deposition process and a nonconformal deposition process. In some embodiments, the conformal deposition process and the nonconformal deposition process are PECVD processes, and a transition between the conformal deposition process and the nonconformal deposition process is effectuated by varying a substrate bias.

Some aspects of the present disclosure relate to a method of manufacturing an IC device. The method includes receiving a semiconductor substrate having a first side and a second side opposite the first side. A front side dielectric structure is formed over the first side. A contact pad is formed over the front side dielectric structure. The semiconductor substrate is thinned from the second side, then a hole is etched through the semiconductor substrate from the second side toward the first side. A conformal oxide layer is deposited on sidewalls of the hole. A first non-oxide dielectric layer is deposited using a plasma-enhanced chemical vapor deposition (PECVD) process with a first substrate bias to produce a conformal nitride layer over the conformal oxide layer within the hole, and a second non-oxide dielectric layer is deposited using a PECVD process with a second substrate bias greater than the first substrate bias to form an overhang near a top portion of the hole. Using the overhang as a mask, an anisotropic dry etch process is used to etch through dielectric material at a bottom of the hole, including at least the first non-oxide dielectric layer. A selective wet etch process is used to expose the contact pad. The wet etch is selective for silicon dioxide relative to the first non-oxide dielectric. A through-substrate via (TSV) electrically coupled to the contact pad is made by filling the hole with a conductive material.

In some embodiments, the front side dielectric structure comprises a plurality of non-oxide dielectric layers. In some embodiments, the method includes extending the hole through one or more of the plurality of non-oxide dielectric layers prior to depositing the conformal oxide layer on the sidewalls of the hole. In some embodiments, etching through dielectric material at the bottom of the hole comprises etching through one or more of the plurality of non-oxide dielectric layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a semiconductor substrate;
a back-end-of-line (BEOL) interconnect structure disposed over the semiconductor substrate, the BEOL interconnect structure comprising a BEOL dielectric structure and a plurality of metal lines that are stacked over one another in the BEOL dielectric structure;
a through substrate via (TSV) extending through the semiconductor substrate to a contact pad; and
a dielectric liner lining sidewalls of the TSV, the dielectric liner comprising:
an oxide layer extending through the semiconductor substrate;
a conformal dielectric layer extending through the semiconductor substrate and disposed between the TSV and the oxide layer; and
a nonconformal dielectric layer thickening the dielectric liner proximate an opposite side of the semiconductor substrate from the contact pad, wherein the conformal dielectric layer and the nonconformal dielectric layer are different in composition from the oxide layer.

2. The IC device of claim 1, wherein the conformal dielectric layer and the nonconformal dielectric layer are silicon nitride.

3. The IC device of claim 1, wherein the contact pad is slotted.

4. The IC device of claim 3, wherein the contact pad is disposed in a metallization layer of a BEOL interconnect structure.

5. The IC device of claim 3, wherein the contact pad is copper.

6. The IC device of claim 1, further comprising a front side dielectric structure between the semiconductor substrate and the contact pad, wherein the front side dielectric structure comprises a plurality of etch stop layers.

7. The IC device of claim 1, wherein the conformal dielectric layer protrudes into the TSV.

8. The IC device of claim 1, wherein the TSV extends through an oxide layer between the semiconductor substrate and the contact pad, and the TSV narrows more rapidly as it extends through the oxide layer than it does as it extends through the semiconductor substrate.

9. The IC device of claim 1, wherein the IC device comprises FinFETs or GAA transistors.

10. The IC device of claim 1, wherein the conformal dielectric layer is thinner than the oxide layer.

11. A method, comprising:
receiving a semiconductor substrate having a first side and a second side opposite the first side;
forming a first dielectric structure over the first side, the first dielectric structure comprising a stack of layers including at least an etch stop layer and a last oxide layer;
forming an interconnect structure over the first dielectric structure, the interconnect structure comprising a second dielectric structure and a metallization layer comprising one or more metal lines within the second dielectric structure, wherein the metallization layer includes a contact pad;
thinning the semiconductor substrate from the second side;
etching a hole through the thinned semiconductor substrate from the second side to the first side;
lining the hole with an oxide liner layer;
depositing a second dielectric layer over the oxide liner layer, wherein the second dielectric layer covers the oxide liner layer and thickens near the second side to form an overhang;
performing an anisotropic dry etch, wherein the anisotropic dry etch etches through material at a bottom of the hole including at least the second dielectric layer, wherein the anisotropic dry etch continues until only oxide layers including the last oxide layer remain between the hole and the contact pad;
performing a selective wet etch to etch through the oxide layers and expose the contact pad, wherein the wet etch is selective for the last oxide layer relative to the second dielectric layer; and
forming a through-substrate via (TSV) electrically coupled to the contact pad by filling the hole with a conductive material.

12. The method of claim 11, wherein the second dielectric layer is silicon nitride.

13. The method of claim 11, wherein performing the selective wet etch comprises etching with hydrofluoric acid.

14. The method of claim 11, further comprising, prior to lining the hole with the oxide liner layer, extending the hole to the last oxide layer.

15. The method of claim 11, wherein depositing the second dielectric layer over the oxide liner layer comprises a conformal deposition process and a nonconformal deposition process.

16. The method of claim 15, wherein the conformal deposition process and the nonconformal deposition process are PECVD processes, and a transition between the conformal deposition process and the nonconformal deposition process is effectuated by varying a substrate bias.

17. A method, comprising:
receiving a semiconductor substrate having a first side and a second side opposite the first side;
forming a front side dielectric structure over the first side;
forming a contact pad over the front side dielectric structure;
thinning the semiconductor substrate from the second side;
etching a hole through the thinned semiconductor substrate from the second side toward the first side;
depositing a conformal oxide layer on sidewalls of the hole;
depositing a first non-oxide dielectric layer using a deposition process with a first substrate bias, whereby the first non-oxide dielectric layer deposits conformally over the conformal oxide layer within the hole;
depositing a second non-oxide dielectric layer using a deposition process with a second substrate bias different than the first substrate bias, whereby the second non-oxide dielectric layer deposits nonconformally and forming an overhang near a top portion of the hole;
etching through dielectric material at a bottom of the hole, including at least the first non-oxide dielectric layer, using an anisotropic dry etch;
performing a selective wet etch to expose the contact pad, wherein the wet etch is selective for silicon dioxide relative to the first non-oxide dielectric; and
forming a through-substrate via (TSV) electrically coupled to the contact pad by filling the hole with a conductive material.

18. The method of claim 17, wherein the front side dielectric structure comprises a plurality of non-oxide dielectric layers.

19. The method of claim 18, further comprising extending the hole through one or more of the plurality of non-oxide dielectric layers prior to depositing the conformal oxide layer on the sidewalls of the hole.

20. The method of claim 18, wherein etching through dielectric material at the bottom of the hole comprises etching through one or more of the plurality of non-oxide dielectric layers.
